(19) United States
(12) Patent Application Publication
(10) Pub. No.: US 2009/0165838 A1
(43) Pub. Date: Jul. 2, 2009

(54) COATED SOLAR PANEL

(76) Inventor: Wiiliam (Bill) BECK, Calgary (CA)

Correspondence Address: SEAN W. GOODWIN, 222 PARKSIDE PLACE, 602-12 AVENUE S.W., CALGARY, AB, T2R 1J3, CA

(21) Appl. No.: 12/018,682

(22) Filed: Jan. 23, 2008

Related U.S. Application Data
(60) Provisional application No. 60/886,317, filed on Jan. 24, 2007.

(51) Int. Cl. H01L 31/042

(52) U.S. Cl. 136/244

(57) ABSTRACT

A solar panel has tubing disposed on an insulating supporting base. The tubing has a heat exchanging liquid flowing therein. The tubing is adhered to the insulating supporting base by a resilient heat transferring coating, forming a collecting surface for exposure to the sun. More particularly, the resilient heat transferring coating is composed of at least one acrylic resin, silica sand, and does not require the addition of water.

### CROSS-REFERENCE

This application claims priority of U.S. provisional application U.S. 60/886,317, filed on Jan. 24, 2007, the disclosure of which is hereby incorporated by reference.

### FIELD OF THE INVENTION

Embodiments of the invention relate to solar panels and, more particularly, to a solar panel having a composite coating.

### BACKGROUND OF THE INVENTION

Solar panels are known which utilize energy from the sun to heat a fluid passing through the panel. A number of different materials have been used to effectively and efficiently absorb the sun's energy and, through heat exchange, heat the fluid therein. The solar panel may be used to provide radiant energy for heating rooms and the like which are adjacent the solar panel or which can be fed by a tubing system connected thereto.

Further, fluid, such as glycol or water, heated in the solar panel can be used for heat exchange to other fluids, such as water in a water heater or optionally can directly heat water for domestic use.

There is interest in developing new solar panels which use a variety of materials that can be produced relatively inexpensively and which are effective and efficient solar collectors.

### SUMMARY OF THE INVENTION

A solar panel has tubing disposed on a support base. The tubing has an inlet and an outlet, for transferring a heat exchanging liquid therethrough, and is adhered to the support base by a resilient heat transferring coating for forming a collecting surface which is exposed to the sun.

In a broad aspect of the invention, a solar panel has a support base, tubing and a resilient heat transferring coating. The tubing has an inlet and an outlet for transferring a heat exchanging liquid therethrough, and is disposed on the supporting base. The resilient heat transferring coating is composed of at least one acrylic resin, silica sand and does not require the addition of water.

The resilient heat transferring coating aids in adhering the tubing to the supporting base and forms a collecting surface for exposure to radiant energy and for transferring the radiant energy to the heat exchanging liquid.

In another aspect of the invention, reinforcing fibers may be added to the resilient heat transferring coating.

In another aspect of the invention, the resilient heat transferring coating provides a surface coverage of reinforcing fibers from about 5% to about 50% when applied to a surface of the supporting base wherein a 20% coverage of the surface comprises of about 3 ounces of reinforcing fibers in a volume of 5 gallons of the at least one acrylic resin.

### BRIEF DESCRIPTION OF THE DRAWINGS

FIG. 1 is a perspective view illustrating a panel according to an embodiment of the invention;

FIG. 2A is a partially exploded perspective view illustrating a tubing grid supported on a foam panel and having an inlet and an outlet, the grid and foam support being coated with a coating material according to an embodiment of the invention; and

FIG. 2B is a partially exploded perspective view according to FIG. 2A illustrating an embodiment for coating the solar panel.

### DETAILED DESCRIPTION OF THE PREFERRED EMBODIMENTS

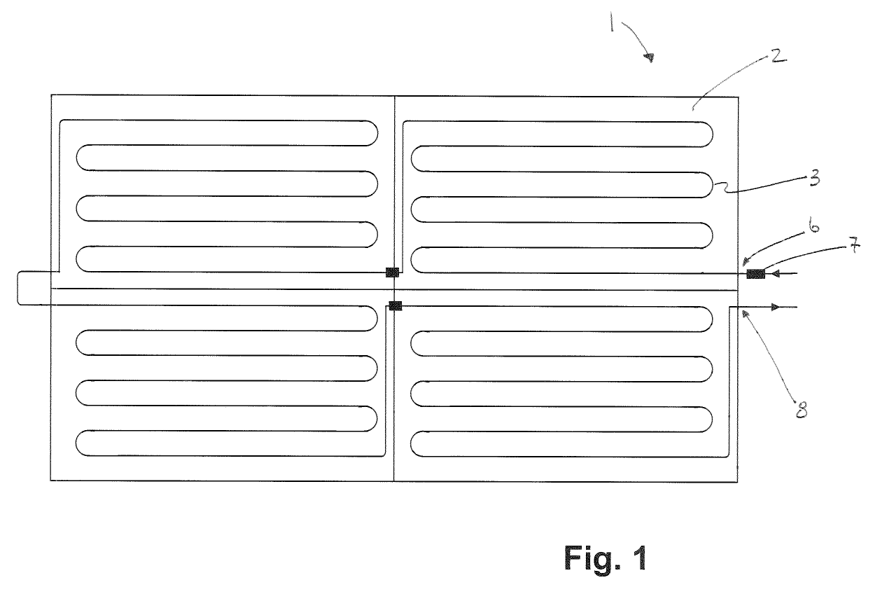

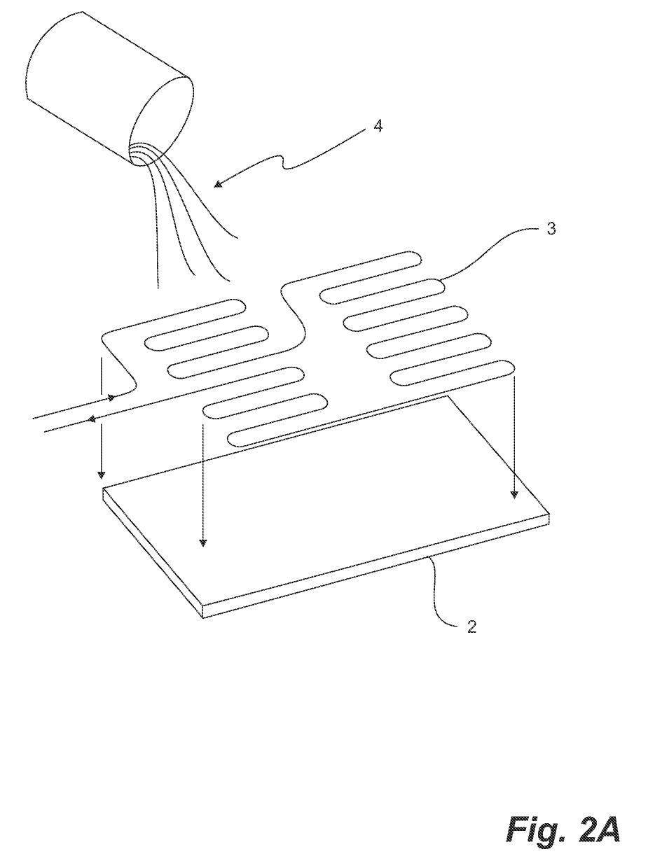

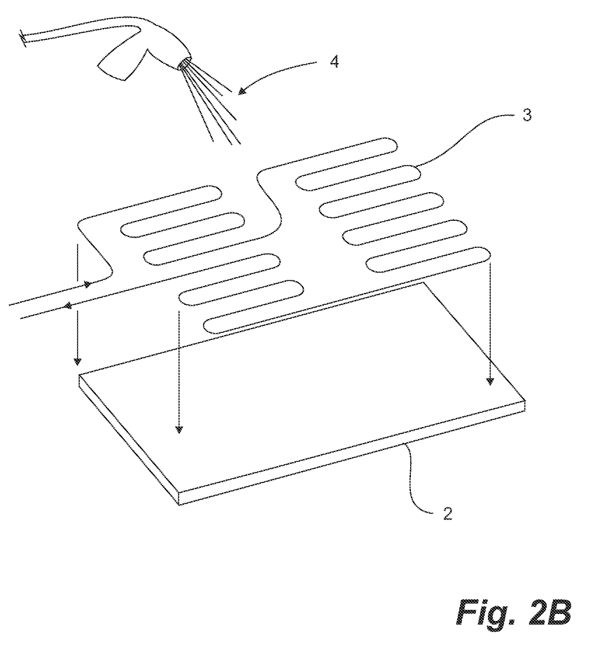

With reference to FIGS. 1, 2a, and 2b, a solar panel comprises tubing disposed on a supporting base. A resilient heat transferring coating is applied onto the tubing and supporting base. The coating aids in adhering the tubing to the supporting base, and further to form a collecting surface which is exposed to radiant energy from the sun. The tubing has an inlet end and an outlet end for transferring a heat exchanging liquid therethrough.

One embodiment of the solar panel 1 comprises an insulating supporting base, such as a foam support panel 2, the foam being typically STYROFOAM® or other such material. A fluidly connected grid of tubing 3 is disposed on the insulating supporting base, such as being laid in loops on the foam panel 2. The tubing may be of a malleable material, such as soft copper tubing. A resilient heat absorbing or transferring coating 4 is applied over the panel 2 and tubing 3.

In one embodiment, the resilient heat transferring coating 4 is poured over the panel 2 and vibrated to spread the coating substantially evenly thereon and adhere the tubing 3 to the foam panel 2. In other embodiments, the resilient heat transferring coating 4 may be rolled on or sprayed onto the tubing 3 and supporting base 2. The resilient heat transferring coating forms a collecting surface 5 over the tubing 3 and supporting base 2.

In an embodiment, the resilient heat transferring coating 4 comprises a 100% acrylic resin to which silica sand is added. In another embodiment, the resilient heat transferring coating comprises a 100% acrylic resin and silica sand to which reinforcing fibers are added.

A black tint or coloring may be applied over the coating 4 or may be added directly to the coating 4 before the coating 4 is applied to the panel 2. In one aspect, the coating 4 acts to protect the solar panel 1 which is exposed directly to the sun, while the black color acts to create a non-reflective, heat transferring surface. Further, Applicant believes that the coating 4 assists with heat transfer between the coating 4 and a heat exchanging liquid therein.

In another embodiment, reinforcing fibers, such as those conventionally used in the concrete industry and typically ranging from about ⅛″ to about ⅝″ long and even up to about 1½″ long, are added to the resin in an effective amount so as to provide a surface coverage of fibers, when applied to the foam panel 2, in a range of from about 5% to about 50%. Most preferably, the fibers used are about ½″ long and are added to provide a surface coverage, when applied to the foam panel 2, of about 20%. In other words, if one were to view the entirety of the surface or any portion thereof (which is at least about 1.5 square inches for ½ inch fibers), one would find a fiber in at least 20% of that viewed surface.

When reinforcing fibers are used, the acrylic resin and fibers are first mixed, such as in a hopper, after which silica sand is added to impart additional strength, uniformity and to improve the aesthetics of the coating. The addition of water is not required in the preparation of this resilient heat transferring coating.

Sufficient silica sand is added in an amount sufficient to obtain a consistency which can be applied to the collecting surface 5 of the foam panel 2 using conventional means, such as by roller or using a texture spray machine such as is known in the industry.

In one embodiment, the acrylic resin may comprise a mixture of one or more acrylic resins, such as Resin #2000 and Resin #2438 available from Akrilon Industries Inc., Calgary, Alberta, Canada. Each of the acrylic resins has a different hardness when applied and therefore when mixed together in varying amounts, the hardness and resilience of the coating 4 can be altered as desired. In one embodiment, the acrylic resin mixture comprises about ⅓ Resin #2000 (hard) and about ⅔ Resin #2438 (soft) to produce a resilient heat transferring coating 4 which is durable and not readily penetrated.

Glass fibers, such as CONTROL™ fibers available from Nycon, Inc., Rhode Island, USA, may be added to the acrylic resin or acrylic resin mixture so as to produce a surface coverage of about 20% fibers. Approximately 3 oz (0.084 kg) of fibers are added to each 5 gallon pail of acrylic resin and the fibers and acrylic are then mixed to disperse the fibers therein.

Silica sand, in an amount ranging from about 2 to about 3-5 gallon pails is then added to the acrylic/fiber mixture and the resulting coating is mixed until a uniform suspension is obtained. Preferably, fine silica sand such as 070 silica sand, available from Target Products Inc. of Burnaby, British Columbia, Canada, is used.

Therefore, in one embodiment, the coating 4 comprises about 1 part by volume of acrylic resin combined with from about 2 to about 3 parts by volume of silica sand and an effective amount of fibers to produce about 20% surface coverage of fibers when applied to the foam panel 2.

The coating 4 when applied to the foam panel 2 and tubing 3 retains some resilience and does not become brittle or crack with use, such as with other cementitious coatings known for use in structural foam-based building materials, regardless that the cementitious coatings may also contain resin and some form of fiberglass or other reinforcement. Cementitious coatings require the addition of water.

In embodiments of the invention, a heat exchanging liquid, such as glycol, may be used in the tubing 3 and is recirculated therethrough for heat exchange or to provide radiant heating.

### EXAMPLE

A solar panel 1 was manufactured using four 2 foot×4 foot panels of STYROFOAM® placed side by side to create a 4 foot×8 foot solar panel 1. About 160 feet of ¼ inch OD soft copper tubing was laid in loops over the panel 2 and was connected at an inlet end 6, using an inlet valve 7 such as a ½″ valve, to a fluid source, such as a water tap. An outlet end 8, discharged water heated by passage through the solar panel 1. The outlet 8 was positioned adjacent the inlet valve 7.

The resilient heat transferring coating was applied to the foam panel 2 using conventional means. It formed a layer of about ⅛ inch to about ¼ inch thick over the foam panel 2 and tubing 3 to form the exterior collecting surface 5.

Tap water was supplied to the inlet 6 of the tubing grid at a temperature of about 45-50° F. The ambient temperature was about 75° F. in full sun at about noon to 1 μm in Calgary, Alberta, Canada. Water was supplied at 400 gal per hour and the solar panel 1 raised the temperature of the water to greater than 170° F.

The embodiments of the invention for which an exclusive property or privilege is claimed are defined as follows:

1. A solar panel comprising:
a supporting base;
tubing disposed on the supporting base, the tubing having an inlet end and an outlet end, for transporting a heat exchanging liquid therethrough; and
a resilient heat transferring coating applied substantially evenly to cover the tubing and the supporting base for forming a collecting surface for exposure to radiant energy and for transferring the radiant energy to the heat exchanging liquid, the resilient heat transferring coating comprising
at least one acrylic resin, and
silica sand.

2. The apparatus of claim 1 wherein the resilient heat transferring coating adheres the tubing to the supporting base.

3. The apparatus of claim 1 wherein the supporting base further comprises an insulating material.

4. The apparatus of claim 1 wherein the supporting base further comprises a polystyrene material.

5. The apparatus of claim 1 wherein the resilient heat transferring coating further comprises reinforcing fibers.

6. The apparatus of claim 5 wherein the resilient heat transferring coating provides a surface coverage of reinforcing fibers from about 5% to about 50% when applied to the surface of the supporting base wherein a 20% coverage of the surface comprises about 3 ounces of reinforcing fibers in a volume of 5 gallons of the at least one acrylic resin.

7. The apparatus of claim 1, wherein the resilient heat transferring coating further comprises a colourant.

8. The apparatus of claim 7 wherein the colourant is added to the resilient heat transferring coating prior to the application of the coating.

9. The apparatus of claim 7 wherein the colourant is substantially evenly applied to substantially cover the resilient heat transferring coating after the application of the resilient heat transferring coating.

10. The apparatus of claim 7 wherein the colourant is black.

11. The apparatus of claim 1 wherein the tubing further comprises a malleable material.

12. The apparatus of claim 1 wherein the tubing is copper tubing.

13. The apparatus of claim 1 wherein the resilient heat transferring coating does not require the addition of water.
